(19) United States
(12) Patent Application Publication
(10) Pub. No.: US 2024/0157505 A1
(43) Pub. Date: May 16, 2024

(54) POLISHING PAD

(71) Applicant: UNIVERSAL PHOTONICS FAR EAST INC., Tokyo (JP)

(72) Inventors: Osamu Kinoshita, Tokyo (JP); Kazuo Shoji, Tokyo (JP)

(21) Appl. No.: 18/417,142

(22) Filed: Jan. 19, 2024

Related U.S. Application Data
(63) Continuation of application No. PCT/JP2021/028983, filed on Aug. 4, 2021.

(51) Int. Cl. B24B 37/24

(52) U.S. Cl. CPC B24B 37/24

(57) ABSTRACT

A polishing pad is formed from a foam body comprising substantially spherical air bubbles. When the density of a pad constituent material is denoted by DM g/cm³, the density of the polishing pad is in the range of 0.36 to 0.70 DM, the variation (standard deviation σ1) of an opening part diameter based on the air bubbles and formed in the surface of the polishing pad is adjusted to 45 μm or less, when the area of a portion surrounded by opening parts based on the air bubbles formed in the surface of the polishing pad is approximated to a circle, the variation (standard deviation σ2) of a diameter of the circle, is adjusted to 35 μm or less, and the air bubbles included in the foam body may be closed cell or open cell.

This application is a continuation of international application no. PCT/JP2021/028983 filed on Aug. 4, 2021 which is incorporated herein and made a part hereof by reference in its entirety and for all purposes.

### TECHNICAL FIELD

The present invention relates to a polishing pad. In particular, it relates to a polishing pad for polishing a semiconductor wafer or the like.

### BACKGROUND ART

The surface of objects to be polished such as semiconductor devices, hard disks, and glasses for liquid crystal displays is polished using polishing liquid (free abrasive grains) and polishing pads and that generally have air bubbles with an air bubble diameter of 1 μm to 5 mm (average air bubble diameter of 10 μm to 200 μm).

In the polishing process, the surface finish of the object to be polished is required as well as the flatness of the object. It is effective to use a so-called hard polishing pad to finish the object to be polished flat, but using a hard pad tends to increase scratches on the surface of the object to be polished so that it is difficult to obtain the required surface finish.

In the prior art, a method of performing multi-step polishing by combining a polishing step that emphasizes flatness and a step that emphasizes surface finish has been proposed (Patent Document 1).

### CITATION LIST

### Patent Document

Patent Document 1: JP-A-H 9-55362
Patent Document 2: JP Patent 6235247

### SUMMARY OF THE INVENTION

### Problems to be Solved by the Invention

In multi-step polishing, if too much emphasis is placed on flatness, the surface finish will be extremely deteriorated, so it will be necessary to carry out steps for improving surface quality for a long time.

On the other hand, since the step for improving the surface quality leads to the deterioration of the flatness, improving the surface quality may impair the flatness achieved in the previous stage. Therefore, it is necessary to adjust and operate the balance between a polishing step that emphasizes flatness and a step that emphasizes surface finish.

In such an operation method, if there is a change in polishing characteristics in one step, it is necessary to adjust the other step to ensure the final quality of the object to be polished. In addition, since the processes that are trade-offs are combined and operated, it is difficult to improve both the flatness and the surface finish at the same time.

When the final product standard of the object to be polished becomes strict, the above problem becomes serious and it becomes difficult to maintain stable finish quality.

Polishing pads are typically manufactured from polyurethane resin foam. The outline of the polishing pad is as follows. The polyurethane resin foam is usually cured and molded by the reaction of a prepolymer containing a polyurethane bond-containing isocyanate compound with a curing agent such as MOCA. This is sliced into a sheet with a slicer to manufacture a polishing pad. Air bubble-based openings are formed on the surface of the polishing pad (FIG. 1 is a schematic cross-sectional view of the conventional polishing pad).

The polishing pad manufactured from this polyurethane resin foam is generally used after roughening the surface of the polishing pad using a dresser composed of electrodeposited diamond or the like (FIG. 2). As shown in FIG. 2, the surface of the polishing pad has a surface structure including openings based on irregularly arranged air bubbles and a roughened polishing surface. The present inventor has found that such a surface structure causes non-uniformity in the polishing result.

The polishing result brought about by such a surface structure, that is, non-uniform contact, was also within the allowable range when the standard required for the surface of the object to be polished was not strict. However, as the standard for polishing has become stricter, it has become impossible to leave such a surface structure unattended.

The present invention has been invented to solve these problems, and an object of the present invention is to improve both the flatness and the surface finish of the object to be polished at the same time. Another object of the present invention is to provide a polishing pad that can stably achieve the required and finished quality of the polishing object whose product standard has become stricter. Further, another object of the present invention is to provide a polishing pad having a uniform contact surface distribution of the polishing pad in contact with the object to be polished. Furthermore, another object of the present invention is to provide a polishing pad capable of suppressing the occurrence of scratches on the object to be polished even if the hardness is high. Furthermore, another object of the present invention is to provide a polishing pad that does not deteriorate the flatness of the object to be polished even if the hardness is low.

### Solution to Problem

The present invention is a polishing pad composed of a foam containing substantially spherical air bubbles in order to solve the above-mentioned problems, and when the density of the pad constituent material is denoted by DM g/cm³, the density of the present polishing pad is in the range of 36 DM or more and 0.70 DM or less. The variation (standard deviation σ1) of a diameter of an opening part based on air bubbles formed on the surface of the polishing pad is adjusted to 45 μm or less, and when the area of a portion surrounded by openings based on air bubbles formed on the surface of the polishing pad is approximated to a circle, the variation (standard deviation σ2) in the diameter of the circle is adjusted to 35 μm or less.

When the hardness of the polishing pad is increased in order to improve the flatness of the object to be polished, the number density of air bubbles in the polishing pad is reduced, and the resin portions between the air bubbles are continuously connected. As a result, when the area of the portion surrounded by the opening based on the air bubble is approximately to a circle, the variation (standard deviation σ2) in diameter of the circles becomes large. On the other hand, when the hardness of the polishing pad is lowered to improve the finish, the number density of air bubbles in the polishing pad becomes high, the air bubbles are connected each other, and the variation (standard deviation σ1) in the opening diameter based on the air bubbles becomes larger. In order to improve both the flatness and the finish of the surface of the object to be polished at the same time, if the density of the pad constituent material is denoted by DM g/cm³, the density of this polishing pad should be in the range of 0.36 DM or more and 0.70 DM or less. Therefore, it is possible to set σ1 to 45 μm or less and σ2 to 35 μm or less.

The material of the polishing pad is not particularly limited, for example, polyurethane resin, polyester resin, polyamide resin, polyimide resin, acrylic resin, polycarbonate resin, halogen-based resin (polyvinyl chloride, polytetrafluoroethylene, polyfluorovinylidene, etc.), polystyrene, olefin resin (polyethylene, polypropylene, etc.), epoxy resin, photosensitive resin, and the like. Among these, polyurethane resin is particularly preferable as a material for polishing pads because it has excellent wear resistance and can be adjusted to have desired physical properties by variously changing the raw material composition.

In the case of polyurethane resin foam, which is a form of polishing pad, the suitable density is in the range of 0.40 to 0.60 g/cm³.

The air bubbles contained in the polyurethane resin foam have an average diameter of 130 μm or less, and are composed of independent air bubbles and air bubbles in which adjacent air bubbles are bonded at the contact point to form an opening, so-called open-air bubbles.

The shore A hardness of the urethane resin foam is preferably in the range of 70 to 95.

### Effects of the Invention

With the polishing pad of the present invention, it is possible to stably achieve the requirements and finished quality of the object to be polished, whose product standards have become stricter. Furthermore, the polishing pad of the present invention has a uniform contact area distribution with the object to be polished on the polishing surface. Even if the hardness of the polishing pad is high according to the object to be polished, it is possible to suppress the occurrence of scratches on the object to be polished. Conversely, even if the hardness of the polishing pad is low, the flatness of the object to be polished will not be deteriorated.

### BRIEF DESCRIPTION OF THE DRAWINGS

FIG. 1 is a schematic cross-sectional view showing a cross-sectional structure of a conventional polishing pad.

FIG. 2 is a schematic cross-sectional view after diamond dressing is performed on a conventional polishing pad.

FIG. 3 is an SEM photograph showing the surface structure of a conventional polishing pad.

FIG. 4 is an SEM photograph showing the surface structure of the polishing pad of the present invention.

FIG. 5 is a histogram showing the diameter distribution of the openings of the conventional polishing pad A.

FIG. 6 is a histogram showing the diameter distribution of the openings of the polishing pad B of the present invention.

FIG. 7 is a histogram showing a diameter distribution when the area of a portion surrounded by an opening of a conventional polishing pad A is approximated to a circle.

FIG. 8 is a histogram showing a diameter distribution when the area of the portion surrounded by the opening of the polishing pad B of the present invention is approximated to a circle.

FIG. 9 is a graph showing a comparison of the number of defects when 18 wafers are polished by each of the conventional polishing pad A and the polishing pad B of the present invention.

FIG. 10 is a graph showing a comparison of surface roughness Ra when 18 wafers are polished by each of the conventional polishing pad A and the polishing pad B of the present invention.

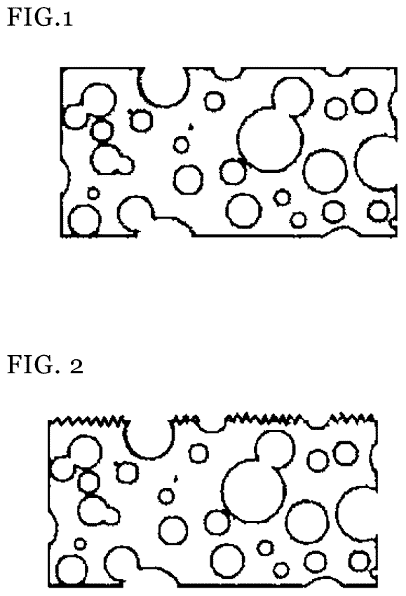

### MODES FOR CARRYING OUT AN INVENTION

The polishing pad, which is one form of the present invention, is composed of a polyurethane resin foam containing substantially spherical air bubbles produced by the method described below. The density of the polyurethane resin foam is preferably in the range of 0.40 to 0.60 g/cm³.

The air bubbles contained in the polyurethane resin foam, which is one form of the present invention, are composed of independent air bubbles and air bubbles in which adjacent air bubbles are bonded at their contact points to form an opening, so-called open-air bubbles. The variation (standard deviation σ1) in the diameter of the openings based on air bubbles formed on the surface of the polishing pad is adjusted to 45 μm or less, and when the area of the portion surrounded by the opening based on air bubbles formed on the surface of the polishing pad is approximated to a circle, The variation (standard deviation σ2) in diameter of the circles is adjusted to 35 μm or less. The Shore A hardness of the urethane foam is preferably in the range of 70 to 95.

As described below, it is indispensable to accurately control the variation in the opening diameter based on the air bubbles of the foam polishing pad in the present invention.

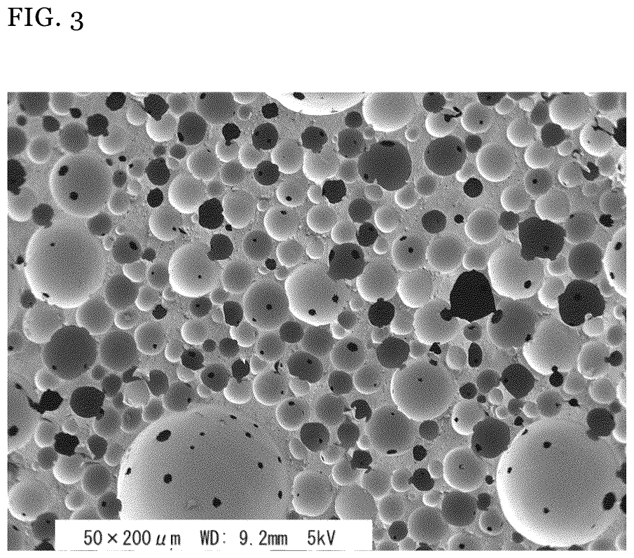

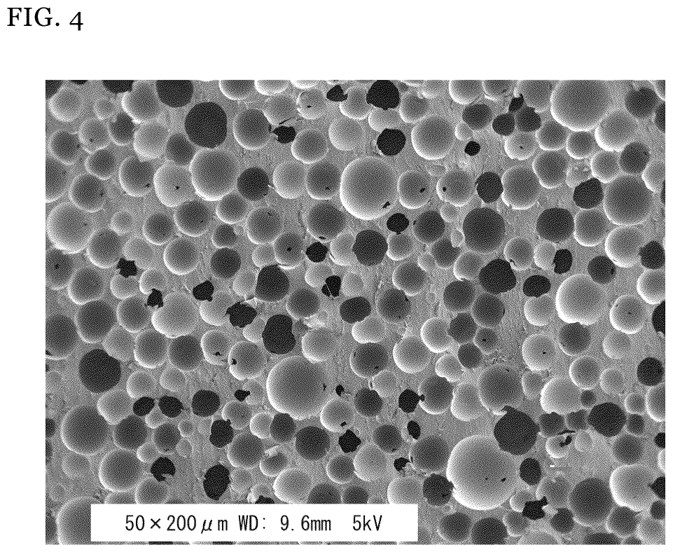

An SEM photograph showing the surface structure of the conventional polishing pad A is shown in FIG. 3. Further, an SEM photograph showing the surface structure of the polishing pad B of the present invention is shown in FIG. 4. As shown in the figure (SEM photograph), the openings existing on the surface of the conventional polishing pad A have a large variation in diameter as compared with the openings existing on the surface of the polishing pad B of the present invention.

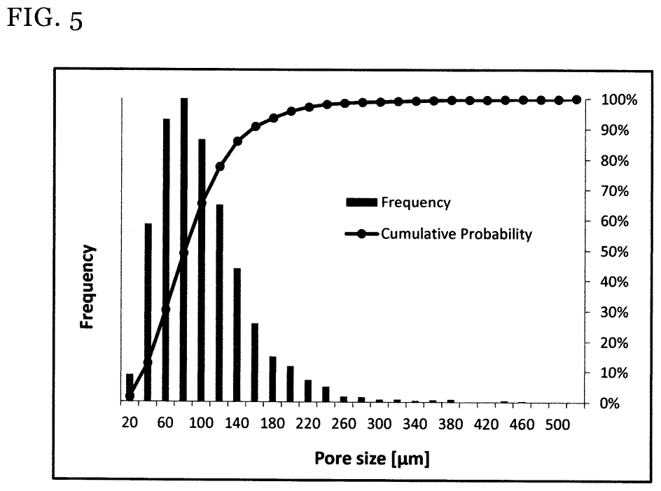

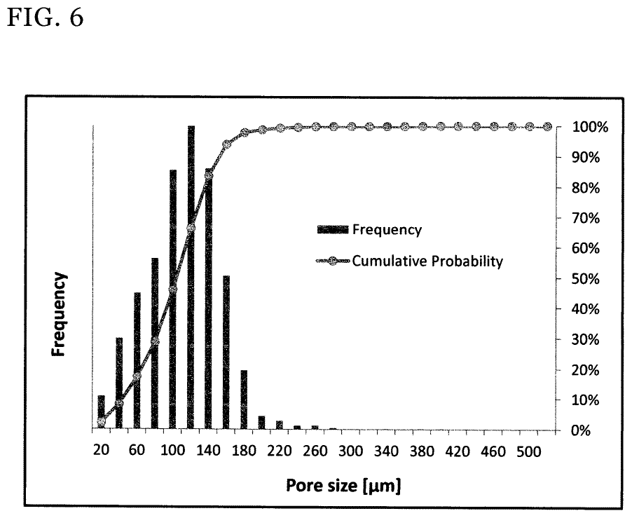

Specifically, FIG. 5 shows a histogram showing the opening diameter distribution of the conventional polishing pad A. The variation (standard deviation σ1) in diameter of the openings is 61 μm. Further, FIG. 6 shows a histogram showing the opening diameter distribution of the polishing pad B of the present invention. The variation (standard deviation σ1) in diameter of the openings is 43 μm.

Further, as shown in the figure (SEM photograph), the area of the portion surrounded by the opening existing on the surface of the conventional polishing pad A is the portion surrounded by the opening existing on the surface of the polishing pad B of the present invention. The variation is large compared to the area.

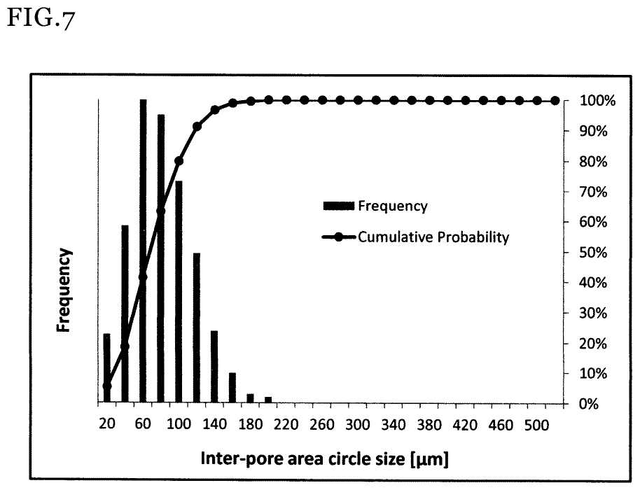

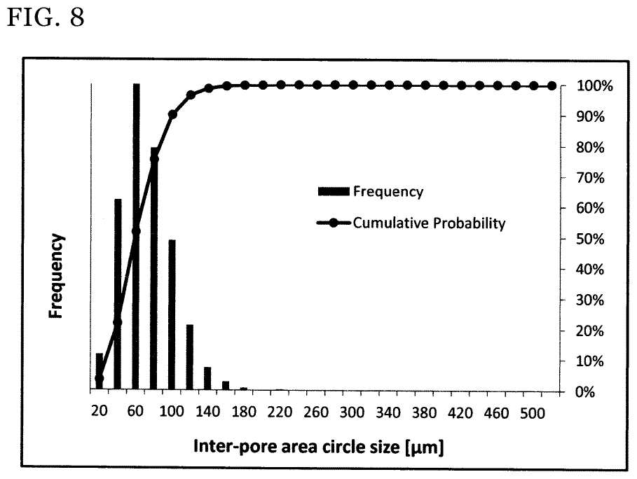

Specifically, FIG. 7 shows a histogram showing the diameter distribution when the area of the portion surrounded by the openings of the conventional polishing pad A is approximated to a circle. The variation (standard deviation σ2) in diameter when the area of the portion surrounded by the openings is approximated to a circle is 36 μm. Further, FIG. 8 shows a histogram showing the diameter distribution when the area of the portion surrounded by the openings of the polishing pad B of the present invention is approximated to a circle. The variation (standard deviation σ2) in diameter when the area of the portion surrounded by the opening is approximated to a circle is 29 μm. The variation (standard deviation σ1) in diameter of the openings and when the area surrounded by the openings is approximated to a circle, the variation (standard deviation σ2) in diameter of the circle were calculated by processing the data obtained by a scanning electron microscope using a commercially available analysis software.

Generally, in the process of forming a foam polishing pad, air bubbles are united with each other, and finally a foam having air bubbles having various sizes is generated. By adjusting the dispersion liquid containing the foaming agent, defoaming agent, and catalyst used, it is possible to control the reaction in which the air bubbles are similar, and as a result, it is almost uniform like the polishing pad of the present invention. It is possible to manufacture a foam polishing pad in which the air bubbles have uniform diameter.

Therefore, on the surface of the polishing pad of the present invention, as shown in FIG. 4, substantially spherical air bubbles are arranged in an orderly manner, and it can be seen that a region formed between the air bubbles, that is, a contact surface is uniformly spread. When the polishing pad is pressed against the object to be polished, the uniformly spread contact surface also disperses the pressing force evenly, and there is no contact surface that becomes locally high pressure. Therefore, the occurrence of scratches can be suppressed. When polishing with a polishing pad having a high hardness, it is possible to obtain flatness while suppressing the generation of scratches.

Further, since the variation in diameter (standard deviation σ1) of the polishing pad of the present invention is suppressed to be small, the compressibility of the polishing pad becomes uniform. Therefore, when polishing with a polishing pad having a low hardness, the required finishing accuracy can be achieved without impairing the flatness of the object to be polished.

The polishing pad of the present invention is manufactured as follows. The polishing pad is manufactured using the in-line mixing device that has been used conventionally. This device is a type of device that continuously mixes raw materials and pours them into a mold.

As a preliminary preparation, a polyisocyanate compound, a polyol compound, a dispersion liquid in which a foaming agent (water) and a silicone-based foam stabilizer are dispersed and diluted in the polyol compound in advance, and a low molecular weight (molecular weight 62 to 350) as a curing agent. A polyamine compound or a low molecular weight polyol compound are prepared.

The polyisocyanate compound has two or more isocyanate groups in the molecule (for example, the diisocyanate compound having two isocyanate groups in the molecule includes m-phenylene diisocyanate and p-phenylene diisocyanate, 2,6-toluene diisocyanate (2,6-TDI), 2,4-toluene diisocyanate (2,4-TDI), naphthalene-1,5-diisocyanate, diphenylmethane-4,4′-diisocyanate, 3,3′-dimethoxybiphenyl-4,4′-diisocyanate, xylylene-1,4-diisocyanate, xylylene-1,3-diisocyanate, diphenylpropane-4,4′-diisocyanate, trimethylene diisocyanate, pentamethylene diisocyanate, hexamethylene diisocyanate, isophorone diisocyanate and cyclohexylmethane-4,4′-diisocyanate). These can be used alone or in combination of two or more.

Examples of the polyol compound include compounds such as diol compounds and triol compounds, for example, low molecular weight polyol compounds such as ethylene glycol and butylene glycol, and polyoxypropylene glycol (PPG) and polyoxytetramethylene glycol (PTMG). Polyether polyol compound with high molecular weight (number average molecular weight 500 to 7000), polyester polyol compound such as reaction product of ethylene glycol and adipic acid, reaction product of butylene glycol and adipic acid, polycarbonate polyol compound, polycaprolactone polyol compound, etc. Examples thereof include high molecular weight polyol compounds are mentioned. These may be used alone or in combination of two or more.

The polyisocyanate compound and the polyol compound are reacted in advance to produce an isocyanate group-containing compound, that is, an isocyanate-terminated urethane prepolymer (hereinafter referred to as “prepolymer”). This prepolymer is used as a main agent to obtain a polyurethane foam by mixing it with a curing agent such as polyamine and a dispersion liquid containing a foaming agent.

It is preferable that the prepolymer in a fluid state is put into a tank and the viscosity at a temperature of 20 to 60° C. is set in the range of 50 to 20000 mPa*s. It is preferable to degas the prepolymer with a vacuum pump to remove the dissolved gas.

In the dispersion liquid containing a foaming agent, water and a foaming agent, a catalyst, and other additives added as necessary are dispersed in a polyol compound that does not participate in foaming. By foaming with this dispersion liquid, it is possible to reduce the formation of mixed spots that are likely to occur when mixed with a prepolymer alone.

As the polyol compound used in this dispersion, for example, a low molecular weight polyol compound such as ethylene glycol or butylene glycol, or a high molecular weight polyol compound such as PTMG, PPG or polyethylene glycol (PEG) can be used.

Water is used as a foaming agent, though not limitedly. It is preferable to use distilled water in order to avoid contamination with impurities and the like.

A surfactant is used as the defoaming agent, but in order to prevent the coalescence of air bubbles and form closed cells, for example, a silicone-based defoaming agent which is a polydimethylsiloxane modified with a polyoxyalkylene chain, etc. can be used.

The amount of this silicone-based defoaming agent used is adjusted by the amount of water used, but is preferably 6.5 to 8.5 parts by weight, preferably 7.0 to 8.0 with respect to 1.0 part by weight of water.

A known catalyst can be used. For example, amine catalysts such as tertiary amines, alcohol amines and ether amines, acetates (potassium, calcium), organic metal catalysts and the like can be mentioned. In this example, the tertiary amineDABCO33LV (EVONIK) is used as a catalyst, but the effect of the present invention is not limited to the case where this catalyst is used. The amount of the catalyst is not particularly limited, but it is preferably used in a ratio of 0.01 to 0.5 parts by mass, preferably 0.05 to 0.3 parts by mass with respect to 100 parts by mass of the prepolymer.

By using this dispersion, the dispersibility of water with respect to the polyurethane resin is excellent, and the foam shape and the distribution of foam become uniform.

The polyamine compound may be further mixed in advance preparation. The polyamine compound reacts with the isocyanate group of the isocyanate group-containing compound.

As the polyamine compound, an aliphatic or aromatic polyamine compound can be used, and there are, for example, ethylenediamine, propylene diamine, hexamethylenediamine, isophorone diamine, dicyclohexylmethane-4,4′-diamine, 3,3′-dichloro-4,4′-diaminodiphenylmethane (hereinafter abbreviated as “MOCA”), diethylmethylbenzenediamine, dimethylthiotoludiamine, 4,4′-methylenebis (3-chloro-2,6-diethylaniline), examples thereof include 1,3-propanediol-bis-(4-aminobenzoate). Further, the polyamine compound may have a hydroxyl group, and examples of such amine-based compounds include methyl diethanolamine, di-(2-hydroxyethyl) ethylenediamine, di-(2-hydroxyethyl) propylene diamine, and di (2-Hydroxyethyl) aniline and the like. These may be used alone or in combination of two or more. In this embodiment, an example in which MOCA is heated to about 120° C. and used in a molten state will be described.

Water as a foaming agent is described, but it is not limited to that. For example, air bubbles can also be formed by a water-soluble substance that retains water, a gas generated by decomposition of a chemical foaming agent, or vaporization of an organic compound. Further, foaming may be formed by a method of mechanically stirring and mixing air, nitrogen, oxygen, carbon dioxide, or an inert gas such as helium or argon (mechanical foaming method), and the above-mentioned plurality of foaming may be formed. Forming means may be combined.

As the chemical foaming agent, for example, at least one selected from the group consisting of N, N′-dinitrosopentamethylenetetramine, azodicarbonamide, 4,4′-oxybisbenzenesulfonyl hydrazide and hydrazodicarbonamide is used. When the thermal decomposition temperature of the chemical foaming agent is 100° C. or higher, early decomposition is further suppressed during the formation of the polyurethane foam so that the dispersed state of air bubbles can be made more even and uniform.

Examples of the water-soluble substance that retains water include water-soluble polysaccharides such as carboxymethyl cellulose, hydroxypropyl cellulose, carboxymethyl chitin, dextrin and cyclodextrin, derivatives thereof, oligos such as chito-oligosaccharide, fructo-oligosaccharide, sucrose and glucose and monosaccharides, cationic surfactants such as, aliphatic amine salts and aliphatic ammonium salts, anionic surfactants such as alkylbenzene sulfonates, sulfonates, alkyl ether sulfates and phosphate ester salts, ether type, ether-ester-type nonionic surfactants, amino acids, proteins, polyvinyl alcohols, polyvinylpyrrolidones, polyvinyl sulfonic acids, and poly (meth) acrylic acids. These may be used alone or in combination of two or more. Since these water-soluble substances easily retain water, the water retained in the water-soluble substance reacts with the isocyanate group-containing compound during the formation of the polyurethane molded body to generate gas and form air bubbles.

By quickly injecting the above-mentioned mixed solution into the mold, the isocyanate group-containing compound and the active hydrogen compound in the mixed liquid are reacted and cured in the mold, and many air bubbles are formed by the foaming agent so that a block-shaped polyurethane foam is obtained. At this time, the isocyanate group-containing compound is cured by reaction with the active hydrogen compound (polymerization or cross-linking), and a polyurethane resin foam having a matrix resin is molded.

The content ratio of the isocyanate group-containing compound in the mixed solution is not particularly limited, but from the viewpoint of more effectively and surely exerting the effect of the present invention, the molar ratio (equivalent ratio) is 0.9 to 1.2, preferably 0.95 to 1.1 with respect to the active hydrogen compound.

The obtained polyurethane foam is sliced to a desired thickness and cut into a desired shape such as a circle to form a sheet-shaped foam pad. A groove having a desired shape may be formed in consideration of the supply of slurry, the discharge of polishing debris and the like during the polishing process.

When using this polishing pad, a pressure-sensitive adhesive tape for attaching the pad is attached to the back surface of the pad. It can be attached to the surface plate of a polishing device via the adhesive tape and used as a polishing pad.

(Comparative examples) Each of the 18 wafers was polished with the polishing pad A according to the conventional technique having the following configuration. The main ingredient is a prepolymer composed of 30 parts by weight of toluene diisocyanate (TDI) and 48 parts by weight of polytetramethylene glycol (PTMG). As the foam stabilizer, 1.0 part by weight of polydimethylsiloxane-based silicone was used, and as the foaming agent, 1.0 part by weight of water was used. After stirring and mixing the above materials under predetermined conditions, 20 parts by weight of dichlorodiaminodiphenylmethane (MOCA) was added as a curing agent, and after continuing mixing for a certain period of time, the mixed solution was cast into a mold and cured. Then, it was allowed to stand in a constant temperature furnace for a predetermined time to complete the reaction, and a solid polyurethane cake was obtained. This solid polyurethane cake was cut into a predetermined thickness with a slicer to manufacture a polishing pad. The main physical property values of the conventional polishing pad A and the polishing pad B of the present invention, which are comparative examples are shown below in Table 1

TABLE 1

| | Average | | | Compres- | Compres- |
|---|---|---|---|---|---|
| Product | pore size | Density | Hardness | sion | sive |
| Name | (μm) | (g/cm³) | Shore A | ratio % | modulus % |
| Conventional | 92 | 0.42 | 86 | 7.7% | 89.8% |
| polishing | | | | | |
| pad A | | | | | |
| Polishing | 101 | 0.43 | 86 | 8.0% | 87.9% |
| pat B of the | | | | | |
| present | | | | | |
| invention | | | | | |

(Example) Each of the 18 wafers was polished with the polishing pad B of the present invention having the following configuration. For the prepolymer that is the main ingredient, the same one as the comparative example was used. However, in this example, the prepolymer was degassed in a closed container for a predetermined time as a preliminary preparation. Further, 1.0 part by weight of the foam stabilizer, 1.0 part by weight of water, and 0.1 part by weight of the catalyst were dispersed in advance in 1.0 part by weight of PTMG to prepare a dispersion liquid. DABCO33LV was used as the catalyst. When these preparations were completed, each component was stirred and mixed so that the mixing ratio of the defoaming agent, water, and curing agent to the prepolymer was the same as in the above comparative example, and then immediately cast into a mold and cured. After that, the same treatment as the conventional polishing pad A was performed to manufacture a polishing pad.

As shown in Table 1, the conventional polishing pad A and the polishing pad B of the present invention have physical property values other than the average pore diameter that are close to each other.

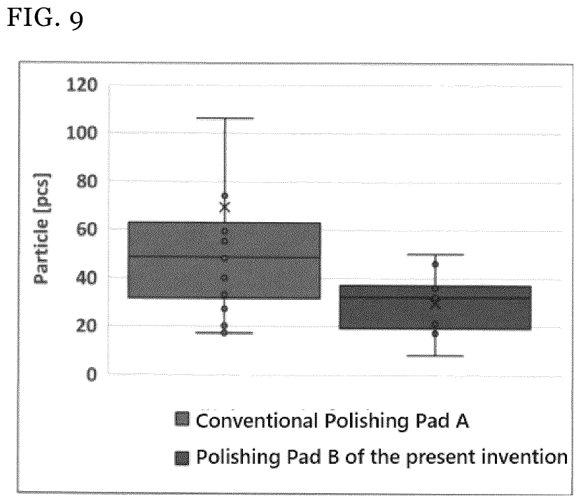

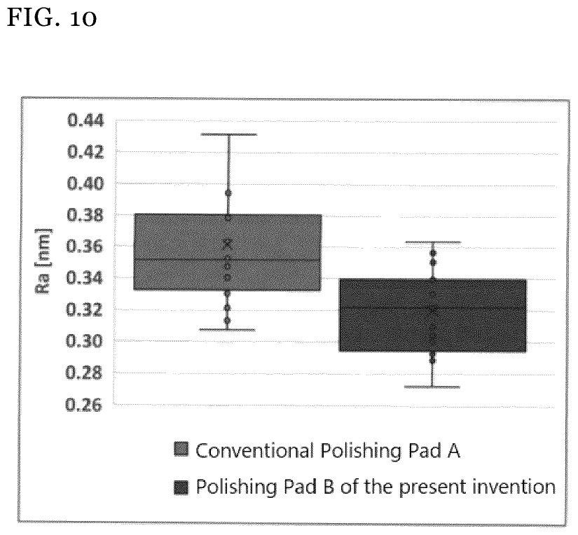

A 6-inch silicon wafer was polished using a 50B single-sided polishing device manufactured by SpeedFam for two types of polishing pads, the conventional polishing pad A and the polishing pad B of the present invention. In order to directly compare the performance of the pads, the usual finish polishing is not performed. The polished silicon wafer was RCA-cleaned, and the number of defects on the wafer surface was counted by a laser particle counter (WM-7S manufactured by Topcon). The measurement result of the number of coarse particles of 0.25 μm or more is shown in FIG. 9. The surface roughness was also measured with an optical interference microscope. The measurement result of the surface roughness Ra is shown in FIG. 10.

As shown in FIGS. 9 and 10, in the polishing pad B of the present invention, improvement in the total number of defects and the surface roughness Ra was confirmed as compared with the conventional polishing pad A. As shown in Table 1, since the conventional polishing pad A and the polishing pad B of the present invention are made of the same raw material and have almost the same density, the physical property values other than the average pore diameter are close to each other. It has become. As a result, the flatness result, which was not specifically disclosed, was also an approximate value. Therefore, the polishing pad B of the present invention was able to improve the surface finish as compared with the conventional polishing pad A while maintaining the flatness.

In this embodiment, a polishing pad using foamed polyurethane is described, but the constituent material of the polishing pad is not limited to polyurethane.

### INDUSTRIAL APPLICABILITY

Although the present invention describes the polishing of a semiconductor (silicon) wafer as an example of the polishing target, the polishing target is not limited to the semiconductor (silicon) wafer, for example, glass, sapphire, various ceramics, metals, and the like.

What is claimed is:

1. A polishing pad comprising a foam body containing substantially spherical air bubbles,
wherein when the density of a pad constituent material is denoted by DM g/cm³, the density of the polishing pad is in the range of 0.36 to 0.70 DM, the variation (standard deviation σ1) of an opening part diameter based on the air bubbles formed in the surface of the polishing pad is adjusted to 45 μm or less,
when the area of a portion surrounded by an opening based on the air bubbles formed in the surface of the polishing pad is approximated to a circle, the variation (standard deviation σ2) of a diameter of the circle is adjusted to 35 μm or less.

2. A polishing pad composed of foam containing substantially spherical air bubbles,
wherein when the density of a pad constituent material is denoted by DM g/cm³, the density of the polishing pad is in the range of 0.36 to 0.70 DM, and when the area of a portion surrounded by an opening based on the air bubbles formed in the surface of the polishing pad is approximated to a circle, the variation (standard deviation σ2) of a diameter of the circle is adjusted to 35 μm or less.

3. The polishing pad as defined in claim 1, wherein the foam is composed of a polyurethane foam.

4. The polishing pad as defined in claim 3, wherein the average air bubble diameter of the urethane foam does not exceed 150 μm.
